(19) United States
(12) Patent Application Publication
(10) Pub. No.: US 2008/0315331 A1
(43) Pub. Date: Dec. 25, 2008

(54) ULTRASOUND SYSTEM WITH THROUGH VIA INTERCONNECT STRUCTURE

(76) Inventors: Robert Gideon Wodnicki, Niskayuna, NY (US); David Martin Mills, Niskayuna, NY (US); Rayette Ann Fisher, Niskayuna, NY (US); Charles Gerard Woychik, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/767,554

(22) Filed: Jun. 25, 2007

(51) Int. Cl. H01L 21/00; H01L 27/14

(52) U.S. Cl. 257/414; 438/48; 257/E21.001; 257/E27.122

(57) ABSTRACT

An ultrasound monitoring system. In one embodiment, an array of transducer cells is formed along a first plane and an integrated circuit structure, formed along a second plane parallel to the first plane, includes an array of circuit cells. A connector provides electrical connections between the array of transducer cells and the array of circuit cells, and an interconnection structure is connected to transfer signals between the circuit cells and processing and control circuitry. The integrated circuit structure includes a semiconductor substrate and a plurality of conductive through-die vias formed through the substrate to provide Input/Output (I/O) connections between the transducer cells and the interconnection structure. The monitoring system may be configured as an imaging system and the processing and control circuitry may be external to the probe unit.

### RELATED APPLICATION

This invention is related to U.S. application Ser. No. 11/743,391 filed May 2, 2007 incorporated herein by reference.

### BACKGROUND OF THE INVENTION

1. Field of the Invention

This invention relates generally to large area array ultrasound imaging and monitoring systems and, more particularly, to systems and methods which integrate high density transducer arrays with processing circuitry.

2. Background Art

Ultrasound imaging systems and computed tomography scan systems use arrays of sensors to generate electrical signals which are processed to provide two-dimensional or three-dimensional image information descriptive of a subject under study. The quality or resolution of the image formed is partly a function of the number of sensors in the imaging array. While providing a large number of sensor elements is desirable to increase the performance in both two-dimensional and three-dimensional imaging applications, substantial increases occur in the size and weight of support circuitry as the number of elements in a sensor array increases. Ideally, but for the size and weight constraints, larger sensor arrays are preferred for a variety of monitoring and imaging applications.

Acoustic transducer cells are typically multi-layered structures comprising piezoelectric materials or acoustically active Micro-ElectroMechanical Structures (MEMS) configured with electronic circuitry in a probe assembly. The electrical signals are further processed by beam forming circuitry, typically external to the probe assembly, to generate and display images of structures being studied. Integrating the beam forming circuitry with the transducer array is desirable as this can mitigate adverse effects resulting from extending relatively long connecting cables between the transducer unit and the support electronics which provide signal processing and control functions. In some cases, the connecting cables can be several meters in length, introducing significant parasitic capacitance. Furthermore, signals received from the transducer assembly through the connecting cables may have a low signal to noise ratio or may be subject to RF interference.

Transducer arrays in ultrasound probe assemblies typically span an area of about 20 cm². For new monitoring and medical imaging applications, such as screening for internal bleeding and tumors, much larger arrays, on the order of 300 cm², are required. For these and other ultrasound imaging applications, larger amounts of wiring and processing circuitry results in larger, heavier and more costly systems.

### BRIEF SUMMARY OF THE INVENTION

In one form of the invention, an ultrasound monitoring system, including a probe unit, has an array of transducer cells formed along a first plane and an integrated circuit structure, formed along a second plane parallel to the first plane, having an array of circuit cells. A connector provides electrical connections between the array of transducer cells and the array of circuit cells, and an interconnection structure is connected to transfer signals between the circuit cells and processing and control circuitry. The integrated circuit structure includes a semiconductor substrate with a plurality of conductive through-die vias formed through the substrate to provide Input/Output (I/O) connections between the transducer cells and the interconnection structure. The monitoring system may be configured as an imaging system and the processing and control circuitry may be external to the probe unit.

In another form of the invention, an embodiment of an ultrasound system formed with a probe unit includes an array of transducer cells formed along a first plane, wherein the transducer cells are formed in or on a transducer substrate having a plurality of conductive through vias for transferring signals. An integrated circuit structure comprising an array of circuit cells is formed along a second plane and a connector provides electrical connections between the through vias in the array of transducer cells and the array of circuit cells. An interconnection structure is connected between the circuit cells and a connector portion to transfer signals between the circuit cells and processing and control circuitry external to the probe unit. A plurality of conductive through-die vias are formed through the integrated circuit structure to provide Input/Output (I/O) connections between the transducer cells and the interconnection structure. The ultrasound system may be configured for image processing and the through vias in the transducer substrate may provide electrical connections between the transducer cells and the connector.

In still another embodiment, a large area transducer assembly is formed by (i) providing an array of transducer cells along a first plane with a first pitch along a first direction, and (ii) providing an integrated circuit device comprising an array of circuit cells. A plurality of conductive through-die vias extend through the circuit cells to make electrical connections between the circuit cells and the transducer cells. A connector is provided for making electrical connections between the conductive through-die vias and the array of transducer cells, and an interconnection structure provides I/O connections to the integrated circuit device.

### BRIEF DESCRIPTION OF THE DRAWINGS

The invention will be more clearly understood from the following description wherein an embodiment is illustrated, by way of example only, with reference to the accompanying drawings, in which:

FIG. 1 illustrates a block diagram of an ultrasound imaging system;

FIG. 2 illustrates in a partial plan view a large area array transducer assembly;

FIG. 3 is a cross-sectional view of the transducer assembly shown in FIG. 2;

FIG. 4 illustrates in a partial cross-sectional view another example of a transducer module;

FIG. 5 illustrates in a partial cross-sectional view another example of a transducer module;

FIG. 6 illustrates in a partial cross-sectional view yet another example of a transducer module; and

FIG. 7 illustrates in a partial cross-sectional view still another example of a transducer module according to the invention.

Like reference numbers are used throughout the figures to indicate like features. Individual features in the figures may not be drawn to scale.

### DETAILED DESCRIPTION OF THE INVENTION

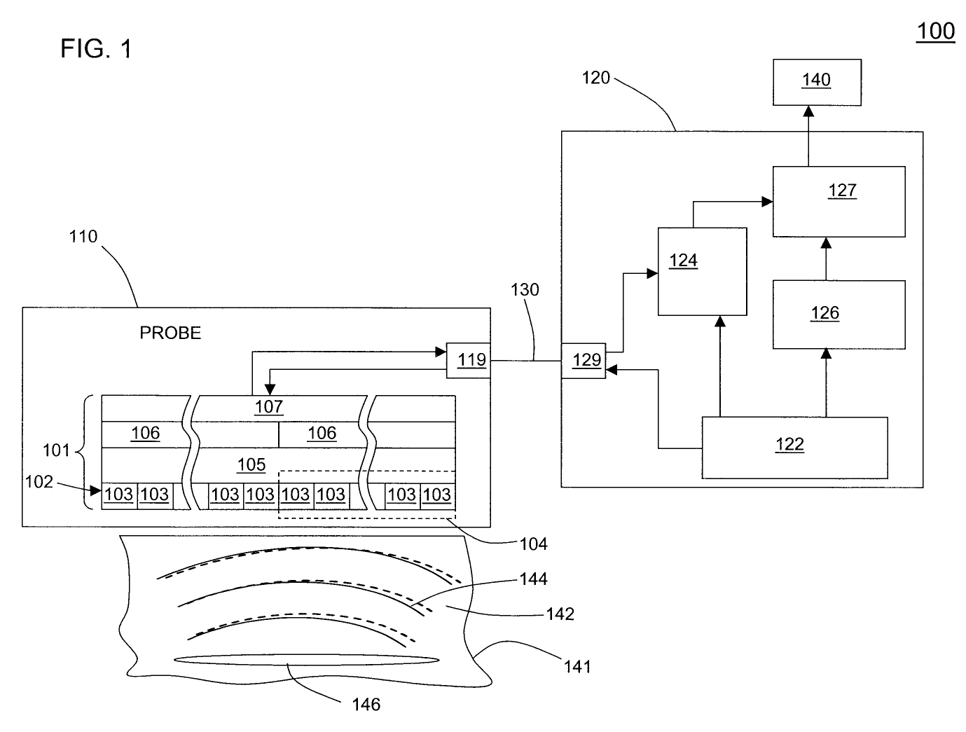

FIG. 1 illustrates an exemplary ultrasound imaging system 100 of the type used for medical imaging, having a probe unit that is relatively light and suitable for hand-held use. More generally, embodiments of the invention include, but are not limited to, acoustic monitoring systems which, generally, incorporate large arrays of transducers.

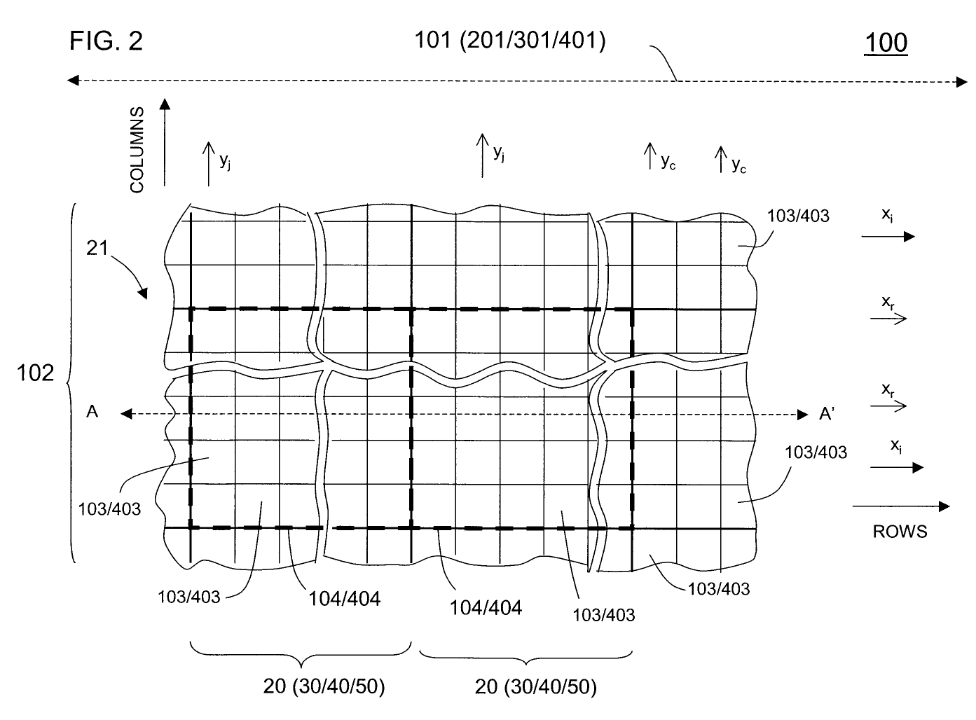

The system 100 includes a probe unit 110 connected to a system console 120 by a multi-channel cable 130 and a display 140 connected to the console 120. The probe unit 110 comprises a transducer assembly 101 having an array 102 of transducer cells 103, a connector 105, a plurality of Application Specific Integrated Circuits (ASICs) 106, and an interconnection structure 107. The console 120 includes a system controller 122, a main beamformer 124, an image processor 126, and a scan converter 127. The transducer array 102 includes a plurality of transducer subarrays 104, each containing a like number of transducer cells 103 arranged in columns and rows. Exemplary transducer subarrays 104 are illustrated in the plan view of FIG. 2. Each subarray 104 is coupled to a corresponding Application Specific Integrated Circuit (ASIC) 106 through the connector 105.

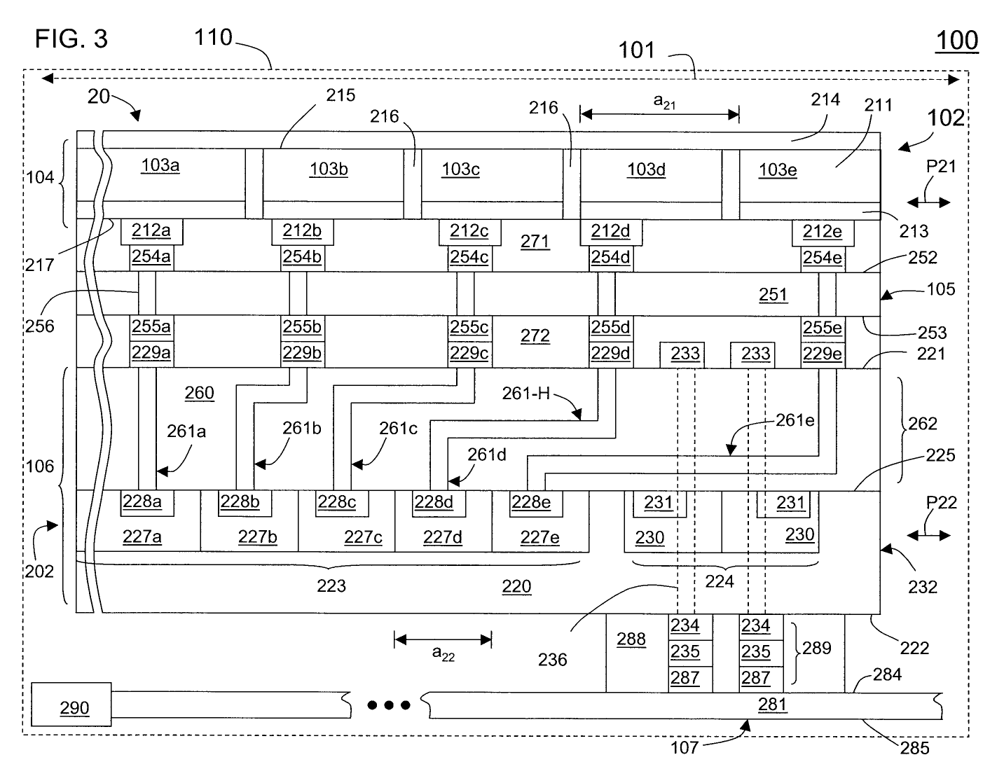

The interconnection structure 107 is coupled to send and receive signals between the ASICs 106 associated with each of the transducer subarrays 104 and the system console 120. According to the embodiments of FIGS. 3-7, the assembly 102 includes a large number of ASICs 106, each connected to a subarray 104 having a large number of transducer cells 103. Information is transferred between the probe unit 110 and the system console 120 via the cable 130 which is coupled between a probe unit line connector 119 in the probe unit 110 and a console line connector 129 in the system console 120.

In the system console 120, the system controller 122 is coupled to the main beamformer 124, the image processor 126, and the ASICs 106 in the probe unit 110 to provide necessary timing signals for the operation of the system 100. Each ASIC 106 provides electronic transmit signals to a transducer subarray 104 to generate ultrasonic pressure waves, herein illustrated as ultrasound waves 142, which may return to the array as acoustic reflections, herein illustrated as ultrasound waves 144, from an area of investigation 146 in an object 141 under study. The main beamformer 124 is coupled to the scan converter 127 to form an image on the display 140.

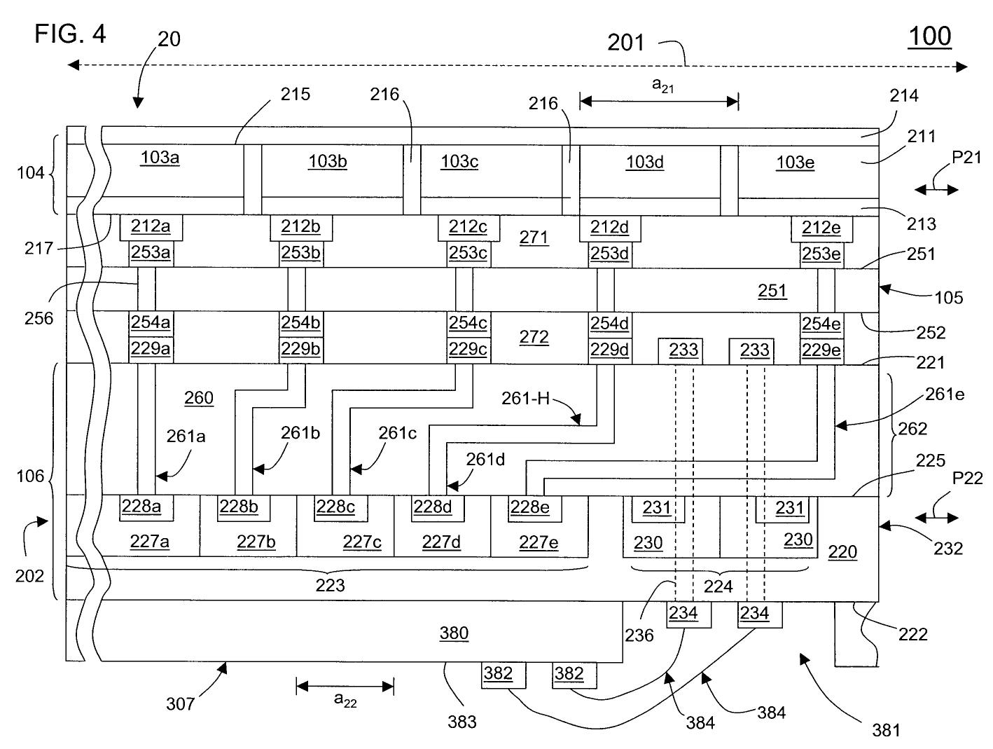

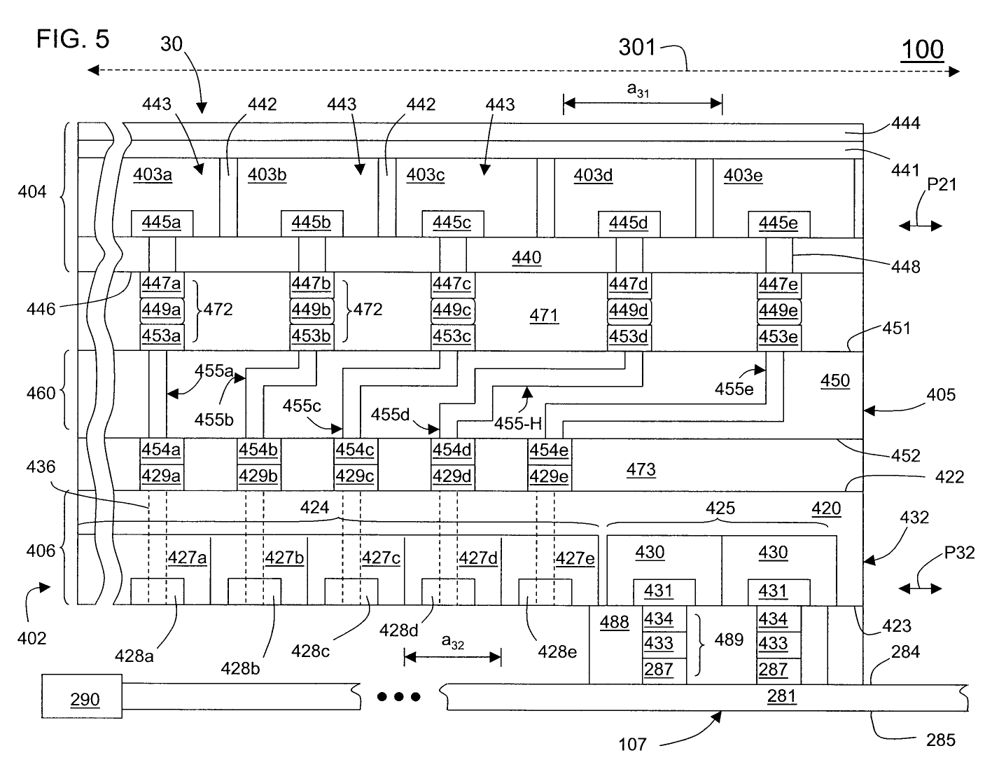

The plan view of FIG. 2 illustrates a portion of the transducer assembly 101 in the ultrasound imaging system 100, comprising a large number of transducer modules 20 formed in an array 21 along rows xᵢ and columns yⱼ. The transducer assembly 101 is functionally interchangeable with one of the transducer assemblies 201, 301, 401, and 501 shown in FIGS. 4-7. The module 20 is functionally interchangeable with one of modules in a group of modules 30, 40, and 50 in FIGS. 5-7. The transducer cell 103 shown in FIG. 1 is functionally interchangeable with the transducer cell 403 shown in FIG. 5 and the subarray 104 of FIG. 1 is functionally interchangeable with the subarray 404 shown in FIG. 5.

Referring to the partial cross sectional view of FIG. 3, taken along the line A-A′ of FIG. 2, an exemplary transducer module 20 in the transducer assembly 101 is shown. Each module 20 comprises a subarray 104 of transducer cells 103 having the cells 103 arranged in rows xᵣ and columns y_{c} such that the subarrays 104, together, form the larger array 102 having all of the transducer cells 103 arranged along the rows xᵣ and columns y_{c}. The rows xᵣ and columns y_{c} and the modules 20 extend along a plane P21 and, in some embodiments, all of the cells 103 are positioned in the same plane. Each module 20, comprising a transducer subarray 104 and a corresponding Application Specific Integrated Circuit (ASIC) 106, is coupled to the interconnection structure 107 to form the transducer assembly 101 as shown in FIG. 1.

Each module 20 includes a transducer subarray 104, an ASIC 106 having a plurality of transducer circuit cells 227 (e.g., 227a-227e), and a connector 105 serving as a circuit connection interface between individual transducer cells 103 in the sub-array 104 and the corresponding circuit cell 227 in the ASIC 106. The connector 105 may be formed of a flexible circuit 251, having a plurality of upper flex contact pads 254 (e.g, 254a-254e) formed along an upper surface 252, and a plurality of lower flex contact pads 255 (e.g, 255a-255e) formed along a lower surface 253, and a plurality of through-flex vias 256 extending between pairs of pads 254, 255. The transducer cells 103 in each subarray 104 are wired through the connector 105 to one of the ASICs 106. The modules 20 in the array 21 are connected to the interconnection structure 107.

In each transducer cell 103 the transducer component 211 may comprise a piezo-electric material such as lead zirconate titanate (PZT) formed over a lower or rear electrode 213 which is connected to an associated transducer contact pad 212 (e.g., one of 212a-212e) formed along a lower surface 217 of the rear electrode 213. A front electrode 214, common to all of the transducer cells 103 in a sub-array 104, may extend across an upper surface 215 of all of the transducer components 211 in the module 20 or subsequent layers may be added to connect the transducer cells 103 so that one electrode may be shared. The illustrated front electrode 214 may be a thin conductive material deposited over the entire transducer subarray 104 to provide a ground electrode for the module 20.

In addition to the piezoelectric material, each transducer component 211 may further comprise one or more matching layers (not shown) which provide suitable acoustic characteristics for transmitting to and receiving acoustic signals from an object under study. Each rear electrode 213 and each associated transducer component 211 is electrically isolated from other electrodes and components by a series of spaces or kerfs 216 which may be created by parallel sawing of the transducer components 211 and the rear electrodes 213. After the transducer cells 103 are separated, additional matching layers (not shown) may be applied to the front face. These layers may be used to reconnect the front face electrode of the transducer cells 103, so that they have one shared electrode. The transducer cells 103 may, for example, be PZT material, a single crystal material (such as PMN-PT or PZN-PT), capacitive Micromachined Ultrasonic Transducer cells (cMUTs), piezoelectric Micromachined Ultrasonic Transducer cells (pMUTs), or PolyVinylidine DiFluoride (PVDF) transducer cells.

The ASIC 106 includes a substrate 220, an upper surface 221, a lower surface 222, a circuit region 223, and an Input/Output (I/O) region 224 formed along an edge 232 of the ASIC 106 and extending into the ASIC substrate 220. The circuit region 223 of the ASIC 106 is formed of a plurality of like transducer circuit cells 227a-227e, each circuit cell 227 having a circuit cell contact 228 (referenced as 228a-228e) along an upper surface 225 of the ASIC substrate 220 and connected to one of the lower flex contact pads 255 for circuit cell connection via a circuit cell bond pad 229 and one of several conductive paths 261 (e.g., 261a-261e) formed in a metallization structure 260 overlying the substrate 220 of the ASIC 106. Each circuit cell 227 sends electrical signals to one transducer cell 103 and receives signals from the same transducer cell 103. The transducer sub-arrays 104 are attached to the flexible circuit 251 with, for example, a first layer 271 of anisotropically conductive adhesive, forming electrical contacts between the upper flex contact pads 254 and the transducer contact pads 212. The ASIC 106 is attached to the flexible circuit 251 with a second layer 272 of anisotropically conductive adhesive, forming electrical contacts between the lower flex contact pads 255 and the circuit bond pads 229. Alternately, electrical connection between lower flex contact pads 255 and the bond pads 229 may be formed with solder balls, gold stud bumps, indium bumps, direct metallic vias or a non-conductive adhesive applied and then subjected to heat and pressure so that the adhesive is displaced as electrical surfaces come into contact with one another. It is also noted that, for various embodiments shown in the figures, various electrodes or contact pads, such as the lower flex contact pads 255, are shown extending beyond the major surface of the associated layer, e.g., circuit 251, while it will be recognized by those skilled in the art that electrodes or contact pads may be formed within the major surfaces of the layers with which they are associated.

The I/O region 224 of the ASIC 106 is formed of a plurality of I/O circuit elements 230, each I/O element 230 having an I/O circuit cell contact 231 along the ASIC substrate upper surface 225. A plurality of through-die vias 236 filled with conductive material such as copper or aluminum provide electrical connections between the I/O bond pads 233 formed on the upper ASIC surface 221 and the backside I/O contact pads 234 formed along the lower ASIC surface 222. The through-die vias 236 are illustrated in phantom lines because they may be in a different plane than that defined by the line A-A′ in FIG. 2. Connection between contacts 231 and bond pads 233 may be effected with formation of additional metallization lines at the time the conductive paths 261 are fabricated, e.g., also in a plane different than that defined by the line A-A′ in FIG. 2. In addition, the through-die vias 236 may effect connections between the circuit cell contacts 231 and I/O contact pads 234 for connection to the interconnection structure 107.

The interconnection structure 107 may be a large area flexible circuit board 281 having a plurality of circuit board contact pads 287. The circuit board 281 illustrated in FIG. 3 is coupled to an ASIC 106 via a plurality of bonded pads 289 with solder bumps 235 formed on the backside I/O pads 234 and the circuit board contact pads 287. A dielectric adhesive 288 is provided around the bonded pads 289. The interconnection structure 107 is coupled to an assembly connector portion 290 for transmitting signals to and receiving signals from the system console 120 (shown in FIG. 1). In other embodiments, the interconnection structure 107 may be formed of a glass substrate coated with an amorphous silicon layer, a flexible polyimide substrate, or a printed circuit board. In still other embodiments, a dematching layer or a backing stack may be placed between the flexible circuit 251 and the transducer subarray 104. Through-vias may be formed across the entire backing stack to provide connections between the transducer cells 103 and the circuit cells 227.

The transducer sub-array 104 extends along the first plane P21 over the I/O region 224 at a uniform first pitch spacing a₂₁. The circuit cells 227 in the ASIC 106 are formed at a second pitch spacing a₂₂ along a second plane P22 parallel to the plane P21 such that a₂₂<a₂₁. This provides room for I/O and other global structures near the edges of the ASIC. The uniform pitch a₂₁ enables tiling of transducer modules 20 to form the large area array transducer assembly 101 with uniformly spaced rows xᵣ and uniformly spaced columns y_{c} across the entire assembly 101 so that there are no significant variations in spacings between transducer cells 103 throughout the rows and columns across the assembly 101.

In the module 20, some of the transducer cells 103 (e.g., cell 103a) are vertically aligned with respect to the circuit cells 227 (e.g., cell 227a) while horizontal offsets exist between others of the transducer cells 103 (e.g., cell 103c) and associated circuit cells 227 (e.g., cell 227c). Connection between transducer cells 103 and circuit cells 227 that are not horizontally aligned with respect to one another is effected with a redistribution system 262 comprising the plurality of conductive paths 261 formed in the ASIC metallization structure 260. Each conductive path 261 provides an electrical connection between an ASIC circuit cell contact 228 and a corresponding circuit cell bond pad 229.

By way of example, for the transducer cell 103a directly overlying a circuit cell 227a, electrical connection between the transducer cell 103a and the circuit cell 227a is provided via a straight conductive path 261a between circuit cell contact 228a and the associated bond pad 229a, a lower flex contact pad 255a, a through-flex via 256, an upper flex contact pad 254a, and a transducer contact pad 212a. For the transducer cell 103d not directly overlying circuit cell 227d, electrical connection between the transducer cell 103d and the circuit cell 227d is provided via a conductive path 261d between a circuit cell contact 228d and the associated bond pad 229d, in the metallization structure 260, a lower flex contact pad 255d, a through-flex via 256, an upper flex contact pad 254d, and a transducer contact pad 212d. The conductive path 261 d includes a horizontal section 261-H, i.e., parallel with the plane P21, to accommodate misalignment between the transducer cell 103d and the circuit cell 227d.

The exemplary path 261d is illustrative of the redistribution function served by the redistribution system 262 (e.g., including the paths 261c, 261d and 261e) in the metallization structure 260 when the pitch a₂₁ of the transducer cells 103 differs from the pitch a₂₂ of the circuit cells 227. The metallization structure 260 also provides conductive paths (not shown) between the I/O contacts 231 and the I/O bond pads 233.

According to an alternate embodiment, FIG. 4 illustrates a transducer assembly 201 in a partial cross-sectional view of the transducer module 20. The view of the assembly 201 is also taken along line A-A′ of FIG. 2 and through a row xᵣ of transducer cells 113 which extends across adjacent modules 20 along the same plane P21 described with reference to FIG. 3. The assembly 201 comprises the modules 20 as described with respect to FIG. 3, and an interconnection structure 307 formed of a backing substrate 380, for example, a silicon, ceramic, or glass substrate.

In one embodiment, the ASIC 106 is thinned to a thickness in range of 25 to 200 microns or in the subrange of 25 microns to 100 microns, prior to the formation of through-die vias in order to reduce the required time and depth through which vias are formed therein. The vias may be created by reactive ion etching or another similar process. Well-known methods of wafer thinning include mechanical grinding, chemical-mechanical polishing (CMP), wet etching, and plasma etching. Typically, mechanical grinding thins wafers by pressing a rotating abrasive disk to the backside of a wafer while CMP typically utilizes a rotating pad with a silica solution.

After thinning the semiconductor substrate 220, vias 236 may be formed through the bulk substrate 220 by plasma etching, laser ablation or other methods of making vias through the semiconductor substrate. In plasma etching techniques, a photoresist mask may be used to protect the material surrounding the vias. Subsequent plasma etching may then produce the vias 236. Resulting through-die vias 236 are illustrated in phantom lines because they are in a different plane than that defined by the line A-A′ of FIG. 2. A metal (e.g., gold, copper, or nickel), may be deposited along a sidewall of each via by, for example, plating. Various other metals such as aluminum, tungsten, nickel, vanadium, or titanium, and alloys thereof may be deposited by plating or deposition methods. The vias may be deposited with metal and filled with a suitable filler material. The filler may be a glass, metal, polymer or other conducting or non-conducting material. In other embodiments it may not be necessary to thin the semiconductor substrate in order to form the through-die vias.

The substrate 380, which includes a plurality of openings 381 (one of which is shown in FIG. 4), functions as a backing substrate for the ASIC substrate 220. The substrate 380 is bonded to the ASIC 106, providing the ASIC 106 with sufficient rigidity for forming the transducer assembly 201. Bonding between the backing substrate 380 and the ASIC 106 may be effected by direct fusion bonding, a well known method for Silicon-On-Insulator (SOI) and Micro-Electro-Mechanical Systems (MEMS) fabrication.

In other embodiments, thermal compression bonding may be used for bonding the ASIC 106 to the backing substrate 380. Thermal compression bonding is a well known bonding method in stacked die packaging and MEMS fabrication, using an intermediate layer for bonding various materials, such as glass, polymers, resists or polyimides, to a substrate. A plurality of ASIC backside bond pads 234 are formed on the lower surface 222 of the ASIC substrate 220 along each opening 381, with each backside bond pad 234 connected to an associated I/O bond pad 233 by a conductive via 236. A plurality of substrate bond pads 382 are formed on the lower surface 383 of the backing substrate 380 along each opening 381. Bonding wires 384 connect the ASIC backside bond pads 234 and the backing substrate bond pads 382 for transmitting and receiving signals from the system console 120 (shown in FIG. 1).

In FIG. 5 a transducer assembly 301 according to another exemplary embodiment is illustrated in a partial cross-sectional view of a transducer module 30. The assembly 301 and the module 30 may, respectively, be interchanged with the assembly 101 and the transducer module 20 of FIG. 3. The view of the module 30 is taken along line A-A′ of FIG. 2 and through a row xᵣ of transducer cells 403 which extends across adjacent modules 30 along the plane P21. The transducer cells 403 are functionally similar to the transducer cells 103 of FIG. 3, but are cMUT transducer cells. The module 30 comprises a subarray 404 of transducer cells 403, a connector 405 formed of a flexible circuit assembly 450, and an ASIC 406. The connector 405 is functionally similar to the connector 105 of FIG. 3 and includes a series of conductive paths 455, each connected between one of a plurality of upper flex contact pads 453 and one of a plurality of lower flex contact pads 454, functioning as a redistribution system 460.

The ASIC 406 is functionally similar to the ASIC 106 of FIG. 3, but includes a series of through-die vias 436. The through-die vias 436 are illustrated in phantom lines to indicate they may be in a different plane than that defined by the line A-A′ of FIG. 2. An array of transducer modules 30 may be connected to the interconnection structure 107 formed of a flexible circuit board 281 as described with respect to FIG. 3.

An array of the cMUT transducer cells 403 may be fabricated on a transducer substrate 440 having a lower surface 446 as illustrated in FIG. 5. The substrate 440 may, for example, be formed from a wafer of heavily doped silicon. For each cMUT transducer cell 403, a thin membrane or diaphragm 441, e.g., a layer of silicon nitride or silicon, is suspended above the substrate 440. The membrane 441 is supported by insulating supports 442, which may be made of silicon oxide or silicon nitride. Cavities 443 between the membrane 441 and the substrate 440 may be air or gas-filled, or wholly or partially evacuated. Typically, cMUT cavities are evacuated as completely as the manufacturing process allows. A film or layer of conductive material, such as aluminum alloy or other suitable conductive material is patterned to form a front electrode 444 on the membrane 441, and another film or layer made of conductive material forms a transducer bottom electrode 445 on the substrate 440. Alternately, the bottom electrode can be formed by appropriate doping of the semiconductor substrate 440. As shown in FIG. 5, a single cMUT cell can make up the transducer cell. However, it is also possible to have multiple cMUT cells with multiple periphery supports 442 within the area of a single transducer cell 403, in which case one through via 448 would supply all the cMUT cells within the area of the single transducer cell 403.

A plurality of through vias 448 are formed in the transducer substrate 440 and filled with conductive material such as aluminum or copper. The through vias 448 provide electrical connections between the transducer bottom electrodes 445 and transducer contact pads 447 formed along the lower surface 446 of the transducer substrate 440.

The ASIC 406, having a plurality of circuit cells 427 (e.g., 427a-427e) in a circuit region 424 and a plurality of I/O circuit cells 430 in an I/O region 425, also includes a series of through-die vias 436 filled with conductive material such as copper. The Input/Output (I/O) region 425 is formed along an edge 432 of the ASIC 406 and extends into the substrate 420 of the ASIC 406. Circuit cell contacts 428 (e.g., 428a-428e) and I/O contacts 431 are formed along a lower surface 423 of the ASIC 406. Each through-die via 436 connects a circuit cell contact 428 to a corresponding backside contact pad 429 (e.g., 429a-429e) formed along the upper surface 422 of the ASIC 406. A solder bump 433 having an under-bump metal pad 434 is formed on each I/O contact 431. A circuit board 281 is coupled to the ASIC 406 via a plurality of bonded pads 489, including flex contact pads 287 formed on the board 281 and under-bump metal pads 434, to transmit signals to and receive signals from the controller unit 122 (shown in FIG. 1) of the ultrasound imaging system 100. A dielectric adhesive 488 is provided around the bonded pads 489.

Electrical contacts between the transducer cells 403 and the connector 405 are made by bonding solder bumps 449 between the transducer contact pads 447 and the upper flex contact pads 453 of the flexible circuit assembly 450. A dielectric adhesive 471 is provided around the bonded pads 472. The flexible circuit assembly 450 may, as shown, be attached to the ASIC 406 with a layer 473 of anisotropically conductive adhesive which facilitates electrical contacts between the backside contact pads 429 and lower flex contact pads 454.

The transducer subarray 404 is formed in rows and columns extending along the plane P21 over the circuit region 424 and over the I/O region 425 at a uniform first pitch spacing, denoted a₃₁. The circuit cells 427 in the ASIC 406 are formed at a second pitch spacing, denoted a₃₂, along a second plane P32 parallel to the plane P21 such that a₃₂<a₃₁. With the pitch spacing a₃₂ of the ASIC circuit cells 427 sufficiently smaller than the pitch spacing a₃₁ of the transducer cells 403, the sub-array 404 of transducer cells 403 overlies the circuit region 424 and the I/O region 425.

In the module 30, horizontal offsets existing between some of the transducer cells 403 and associated circuit cells 427 are accommodated by the flexible circuit assembly 450 having a plurality of conductive paths 455 (e.g., 455a-455e), a plurality of upper flex contact pads 453 (e.g., 453a-453e) and a plurality of lower flex contact pads 454 (e.g., 454a-454e). The circuit assembly 450 is attached to the transducer subarray 404 with a layer 471 of dielectric adhesive material.

Each conductive path 455 provides an electrical connection between a backside ASIC bond pad 429 and a corresponding transducer contact pad 447. By way of example, for the transducer cell 403a directly overlying a circuit cell 427a, a straight vertical conductive path 455a makes connection between the transducer contact pad 447a and the associated backside bond pad 429a via the upper flex contact pad 453a and the lower flex contact pad 454a. For the transducer cell 403d, connection between the transducer contact pad 447d and the associated bond pad 429d is made with a conductive path 455d having a horizontal section 455-H to accommodate the misalignment between the transducer cell 403d and the corresponding circuit bond pad 429d. The exemplary path 455d is illustrative of the redistribution function served by the flexible circuit assembly 450 when the pitch a₃₁ of the transducer cells 403 differs from the pitch a₃₂ of the circuit cells 427.

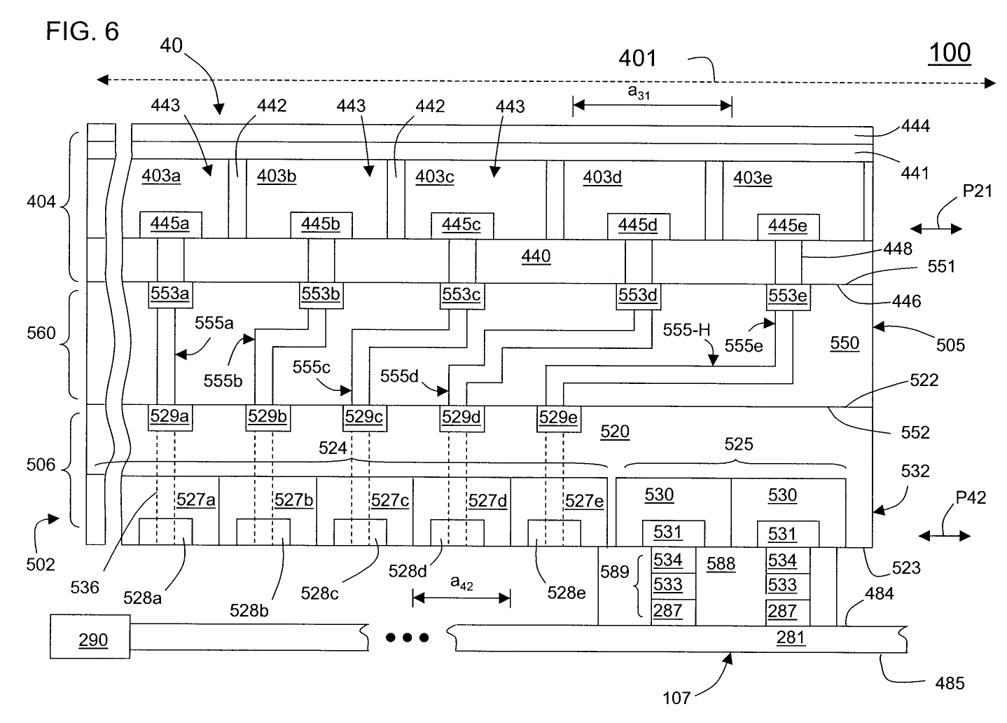

In FIG. 6 a transducer assembly 401 according to another embodiment is illustrated in the partial cross-sectional view of a module 40. The assembly 401 and the module 40 may, respectively, be interchanged with the assembly 101 and the transducer module 20 of FIG. 3. The view of the module 40 is also taken along line A-A′ of FIG. 2 and through a row xᵣ of transducer cells 403 which extends across adjacent modules 40 along the plane P21. In the embodiment of FIG. 6, the transducer module 40 comprises the transducer subarray 404 as described with respect to FIG. 5, an ASIC 506 formed on a substrate 520 with an upper surface 522, and a lower surface 523, and a connector 505 formed of an interposer 550. The ASIC 506, having a circuit region 524 and an I/O region 525, is functionally similar to the ASIC 106 of FIG. 3, but does not provide a redistribution function. The I/O region 525 is formed along an edge 532 of the ASIC 506 and extends into the ASIC substrate 520. The interposer 550 formed on the upper surface 522 of the ASIC 506 serves as a circuit connection interface between each cell 403 in the sub-array 404 and the circuit region 524, functioning as a redistribution system 560. An array of transducer modules 40 may be connected to the interconnection structure 107 as described with respect to FIG. 3. The ASIC 506 includes a series of through-die vias 536 filled with conductive material such as copper. The ASIC 506 may be thinned to a thickness in the range of 25 microns to 200 microns, or 25 microns to 100 microns, prior to the formation of the through-die vias 536. The through-die vias 536 are illustrated in phantom lines because they may be in a different plane than that defined by the line A-A′ in FIG. 2. The ASIC 506 is attached to the lower surface 552 of the interposer 550 by direct fusion bonding. In other embodiments, the ASIC 506 may be attached to the lower surface 552 of the connector interposer by thermal compression bonding. Alternately, the interposer 550 may comprise a post-processed layer of Benzocyclobutene or other low-k dielectric material with metallization formed therein.

The exemplary interposer 550, formed of a semiconductor substrate, includes a plurality of conductive paths 555 (e.g., 555a-555e), each providing electrical connection between a backside contact pad 529 (529a-529e) formed along the upper surface 522 of the ASIC 506 and corresponding connector contact pads 553 formed along the upper surface 551 Of the interposer 550. By way of example, for the transducer cell 403a directly overlying a circuit cell 527a, a straight vertical conductive path 555a makes connection between the connector contact pad 553a and the associated bond pad 529a. For the transducer cell 403d, connection between the connector contact pad 553d and the associated bond pad 529d is made with a conductive path 555d having a horizontal section 555-H to accommodate the misalignment between the transducer cell 403d and the circuit cell 527d. The transducer subarrays 404 are attached to the upper surface 551 of the interposer 550 by direct fusion bonding, connecting the through-vias 448 filled with conductive material and the connector contact pads 553. In other embodiments, the subarrays 404 may be attached to the upper surface 551 of the connector 550 by thermal compression bonding. In other embodiments, an interposer may be formed of a flexible circuit, a rigid substrate such as Si, or ceramic, or a laminated backing stack.

The circuit region 524 and the I/O region 525 are formed of a plurality of like transducer circuit cells 527 and a plurality of I/O elements 530. The circuit cell contacts 528 (e.g., 528a-528e) and the I/O contacts 531 are formed along the lower surface 523 of the ASIC 506. Each through-die via 536 connects a circuit cell contact 528 to a corresponding backside contact pad 529 formed along the upper surface 522 of the ASIC 506.

A solder bump 533 having an under-bump metal pad 534 is formed on each I/O contact 531. Circuit board 281 is coupled to the ASIC 506 via a plurality of bonded pads 589 formed with solder bumps 533 and the flex contact pads 287 for transmitting signals to and receiving signals from the system console 120 (shown in FIG. 1). A dielectric adhesive 588 is provided around the bonded pads 589.

Manufacturing of large area array transducer assemblies is simplified by provision of through-vias in the ASIC die and/or through-vias in the transducer substrate such as has been illustrated for numerous embodiments. Through-vias 236 in the ASIC 106 of FIGS. 3 and 4 provide reliable I/O connections, either in conjunction with bump bonding to a suitable large area patterned substrate 281 as illustrated in FIG. 3; or by wire bonding to a backing substrate 380 as illustrated in FIG. 4. With a rigid backing substrate 380 as part of the transducer assembly 201, the ASICs 106 may be thinned to an overall thickness between 25 microns and 100 microns to reduce the etch time and via diameter needed to form through-vias 236 in the ASIC 106. Through-vias 448 in the transducer substrate 440 can provide electrical connections between the transducer cells 403 and the circuit cells 427 as shown in FIGS. 5-6. With an interposer 550 functioning as a backing substrate to the ASIC 506 of FIG. 6, the ASIC 506 may be thinned to an overall thickness between 25 microns and 100 microns to reduce the etch time and via diameter needed to form through-vias 536 in the ASIC 106 as illustrated in FIG. 6. The interposer 550 may be bonded to the ASIC 506 by direct fusion bonding or by thermal compression bonding.

Numerous embodiments illustrate integrated circuitry, such as the ASIC 106, providing electronic transmit and control signals to a transducer subarray to generate ultrasonic pressure waves; and to receive signals from the subarray. It is noted, however, that the circuitry supporting transmit and receive functions may, for example in an imaging system, reside in other components within a probe unit or system console.

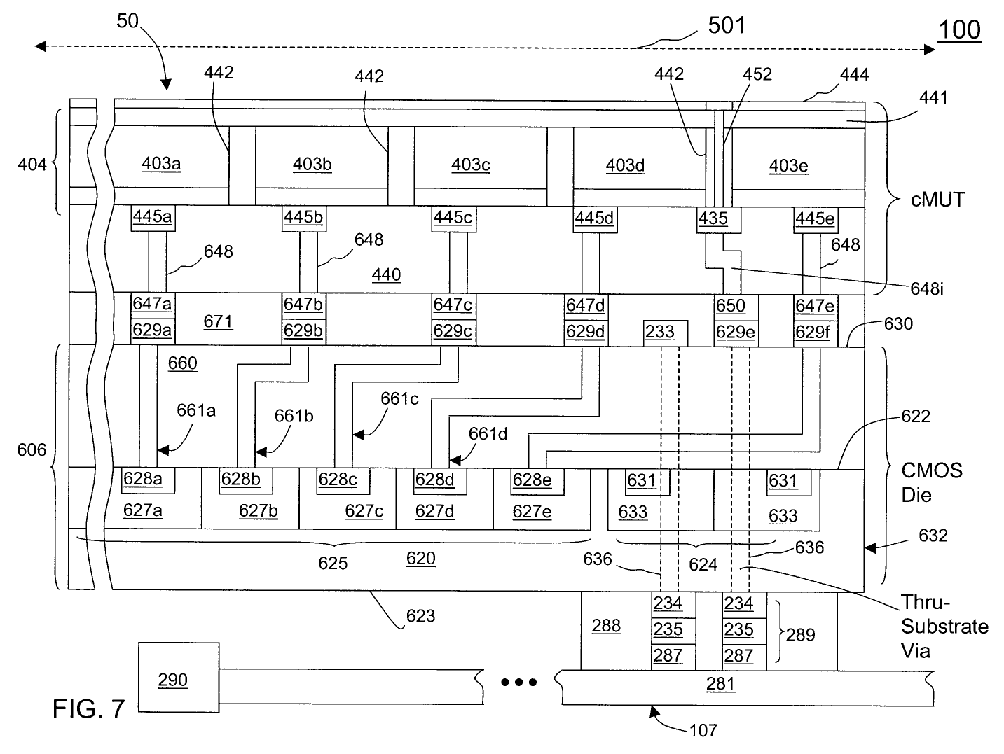

While exemplary embodiments of the invention have been illustrated and described, numerous other connections, such as bias voltage lines, have not been illustrated. These may be routed in various ways including with the use of redistribution layers and through-die vias. By way of further example, see the partial cross-sectional view of a module 50 in FIG. 7, which illustrates a transducer assembly having a ground connection routed through a via formed in a cMUT array and through an ASIC. The view of the module 50 is taken along the line A-A′ of FIG. 2 and through a row xᵣ of transducer cells 403 which extends across adjacent modules 50 along the plane P21. In the embodiment of FIG. 7, the transducer module 50 comprises a cMUT transducer subarray 404 formed on a semiconductor substrate 440 as described with respect to FIGS. 5 and 6 with a front electrode 444 positioned over a membrane 441 and with the membrane suspended over insulating supports 442. The individual cells 403 include bottom electrodes 445 (445a-445e) for receiving signals from ASIC circuit cells.

An ASIC 606 is formed on a substrate 620 with an upper surface 622, a lower surface 623, an Input/Output (I/O) region 624 and a circuit region 625. The I/O region 625 is formed along an edge 632 of the ASIC 606, extending into the substrate 620. The circuit region 625 of the ASIC 606 is formed of a plurality of like transducer circuit cells 627 (referenced as 627a-627e), each circuit cell having a circuit cell contact 628 (referenced as 628a-628e). The contacts 628 are formed along the upper surface 622 of the ASIC substrate 620 and connected to one of the transducer contact pads 647 for circuit cell connection via one of several conductive paths 661 (e.g., 661a-661e). The paths 661 are formed in a metallization structure 660 overlying the substrate 620 of the ASIC 606. Each conductive path 661 extends between a cell contact 628 and an ASIC contact pad 629 formed along an upper surface 630 of the metallization structure 660.

In the example embodiments each circuit cell 627 sends electrical signals to one transducer cell 403 and receives signals from the same transducer cell 403. To effect this connection for the module 50, the transducer sub-arrays 404 are attached to the metallization structure 660 with, for example, a layer 671 of anisotropically conductive adhesive, forming electrical contacts between the upper ASIC contact pads 629 formed along the surface 630 and the transducer contact pads 647. Alternately, electrical connections may be formed with solder balls, gold stud bumps, indium bumps, direct metallic vias or a non-conductive adhesive applied and then subjected to heat and pressure so that the adhesive is displaced as electrical surfaces come into contact with one another.

The I/O region 624 of the ASIC 606 is formed of a plurality of I/O circuit elements 633, each I/O element 633 having an I/O circuit cell contact 631 along the ASIC substrate upper surface 622. A plurality of through-die vias 636 filled with conductive material such as copper or aluminum may provide a variety of electrical connections such as shown for the vias 236 of FIG. 3, the vias 436 of FIG. 5 and the vias 536 of FIG. 6. Further, bias voltages and other signals, e.g., ground, etc., may be routed from a discrete component, e.g., a circuit board, to the cMUT array by a combination of conductive through vias 648 formed in the cMUT semiconductor substrate 440 and through vias 636 formed in the ASIC 606. In the example of FIG. 7, the vias 636 may effect connections between a metallization contact pad 629 and a circuit board 281 which may be electrically connected to the ASIC 606 via a plurality of bonded pads 289 as described with respect to FIG. 3. Through-vias 648 filled with conductive material extend through the cMUT substrate 440 to effect connections to the rear electrodes 445 and to the front electrode 444 of the cMUT subarray 404.

In this example, a conductive via 452 is formed within an insulating support 442 between adjacent transducer cells 403 to connect the front electrode 444 to a contact 435 on the cMUT substrate 433. Further routing extends from the contact 435 through a substrate via 648i to a cMUT substrate contact 650 at which point connection is made to an electrode 629e through the layer 671 of conductive adhesive to provide further connection along a via 636 to contact the board 281 (interconnection structure 107) through the bond pads 289. As noted for other illustrated examples, through-die vias 636 are illustrated in phantom lines because they may each be in a different plane than that defined by the line A-A′ in FIG. 2.

Thus, as illustrated in FIG. 7, a module may further include the combination of a series of vias 452 each formed within one of the spaces 442 between individual ones of the transducer cells 403 for connection through vias 648 in the cMUT substrate 440 to effect various signal or supply connections to the ASIC 606 or a circuit board or other component. While numerous other connections have not been illustrated, it is to be understood that these may be routed in various ways including with the use of redistribution layers and through-die vias.

The illustrated embodiments have included integrated circuitry, such as the ASIC 106, providing electronic transmit and control signals to a transducer subarray to generate ultrasonic pressure waves and to receive signals from the subarray. It is noted, however, that the circuitry supporting transmit and receive functions may, for example in an imaging system, reside in other components within a probe unit or system console. While multiple embodiments of the invention have been described, the invention is not so limited. For example, the embodiment of FIG. 4 may be modified by inverting the ASIC 106 and forming through-die vias in the circuit cell area 223. Numerous other modifications, variations, substitutions and equivalents will occur to those skilled in the art without departing from the spirit and scope of the present invention as described in the claims.

We claim:

1. An ultrasound monitoring system comprising a probe unit including:
an array of transducer cells formed along a first plane;
an integrated circuit structure comprising an array of circuit cells formed along a second plane parallel to the first plane;
a connector providing electrical connections between the array of transducer cells and the array of circuit cells; and
an interconnection structure connected to transfer signals between the circuit cells and processing and control circuitry, wherein the integrated circuit structure includes a semiconductor substrate with a plurality of conductive through-die vias formed through the substrate to provide Input/Output connections to the interconnection structure.

2. The system of claim 1 configured as an imaging system.

3. The system of claim 1 wherein the system includes the processing and control circuitry and the processing and control circuitry is positioned external to the probe unit.

4. The system of claim 1 wherein the array of transducer cells includes one or more transducer modules, each module comprising a subarray of transducer cells and a subarray of interface circuit cells.

5. The system of claim 1 wherein the transducer cells are cMUTs formed in and about a semiconductor substrate.

6. The system of claim 1 wherein the transducer cells are cMUTs of the type having insulative regions formed between adjacent cells, a front electrode common to multiple ones of the transducer cells and a plurality of rear electrodes each connected to transfer a signal between a different circuit cell of the integrated circuit structure and a transducer cell, each rear electrode positioned between the integrated circuit structure and the front electrode, the system further including a conductive via formed within a cMUT insulative region connecting the front electrode to the interconnection structure.

7. The system of claim 1 wherein the integrated circuit structure includes a metallization structure providing a redistribution function including a conductive segment parallel with the first plane in order to accommodate an offset between one of the transducer cells and one of the circuit cells.

8. The system of claim 5 wherein the connector includes a series of conductive paths, each connected between one of a plurality of upper flex contact pads and one of a plurality of lower flex contact pads, functioning as a redistribution system.

9. The system of claim 5 wherein a plurality of through-vias are formed in the transducer semiconductor substrate.

10. The system of claim 1 wherein the semiconductor substrate has a thickness in the range of 25 microns to 200 microns.

11. The system of claim 1 wherein the integrated circuit structure is bonded to a backing substrate taken from the group consisting of a semiconductor substrate and a glass substrate coated with an amorphous silicon layer.

12. The system of claim 1 wherein the connector comprises a flexible circuit assembly having one or more flexible circuits for routing electrical connections between the integrated circuit cells and the transducer cells.

13. The system of claim 1 wherein the interconnection structure comprises a flexible circuit assembly having one or more flexible circuit boards for routing electrical connections to the processing and control circuitry.

14. An ultrasound monitoring system comprising a probe unit including:
an array of transducer cells formed along a first plane and an integrated circuit structure comprising an array of circuit cells formed along a second plane parallel to the first plane, the array of transducer cells including insulative regions formed between adjacent transducer cells, a front electrode common to multiple ones of the transducer cells and a plurality of rear electrodes each connected to transfer a signal between a different circuit cell of the integrated circuit structure and a transducer cell, each rear electrode positioned between the integrated circuit structure and the front electrode;
a connector configured to effect the electrical connections between the rear electrodes and circuit cells in the integrated circuit structure; and
an interconnection structure connected to transfer signals between the circuit cells and processing and control circuitry, the system further including a conductive via formed in one of the insulative regions between adjacent ones of the transducer cells effecting an electrical connection to the interconnection structure.

15. The system of claim 14 wherein the integrated circuit structure includes a semiconductor substrate with a plurality of conductive through-die vias formed through the substrate to provide Input/Output connections to the interconnection structure.

16. The system of claim 14 wherein the transducer cells are cMUTs formed in and about a semiconductor substrate.

17. The system of claim 14 wherein the conductive via formed within one of the insulative region effects a ground connection to the front electrode.

18. An ultrasound system comprising a probe unit including:
an array of transducer cells formed along a first plane, wherein the transducer cells are formed in or on a transducer substrate having a plurality of conductive through vias for transferring signals;
an integrated circuit structure comprising an array of circuit cells formed along a second plane;
a connector providing electrical connections between the through vias in the array of transducer cells and the array of circuit cells; and
an interconnection structure connected between the circuit cells and a connector portion to transfer signals between the circuit cells and processing and control circuitry external to the probe unit, wherein a plurality of conductive through-die vias are formed through the integrated circuit structure to provide Input/Output connections between the transducer cells and the interconnection structure.

19. The system of claim 18 wherein the system is configured for image processing and the through vias in the transducer substrate provide electrical connections between the transducer cells and the connector.

20. A method of forming a large area transducer assembly, comprising the steps of:
providing an array of transducer cells along a first plane with a first pitch along a first direction;
providing an integrated circuit device comprising an array of circuit cells with a plurality of conductive through-die vias extending through the circuit cells to make electrical connections between the circuit cells and the transducer cells;
providing a connector for making electrical connections between the conductive through-die vias and the array of transducer cells; and
providing an interconnection structure for effecting input/output connections to the integrated circuit device.

21. The method of claim 20 further including the step of providing an array of transducer cells formed in or on a transducer substrate, the transducer substrate having a plurality of conductive through vias for making electrical connections between the transducer cells and the conductor.

22. The method of claim 20 wherein the step of providing the integrated circuit device includes providing a substrate, thinning the substrate in the range of 25 to 200 microns and forming the through-die vias after thinning the substrate.

23. The method of claim 22 further including steps of:
providing a backing substrate; and
bonding the thinned integrated circuit device and the backing substrate by direct fusion bonding.

24. The method of claim 22 further including the steps of:
providing a rigid connector; and
bonding the integrated circuit device and the connector by direct fusion bonding or thermal compression bonding.

25. The method of claim 23 wherein the integrated circuit device is thinned to an overall thickness of between 25 microns and 200 microns.

26. The method of claim 20 wherein the step of providing the integrated circuit device includes providing a substrate, thinning the substrate to an overall thickness ranging between a characteristic junction depth of the CMOS fabrication process and 200 microns and forming the through-die vias after thinning the substrate.

27. The method of claim 21 further including providing a dematching layer or acoustic backing between the transducer cells and the connector.
